(19) United States
(12) Patent Application Publication
(10) Pub. No.: US 2025/0062281 A1
(43) Pub. Date: Feb. 20, 2025

(54) SEMICONDUCTOR PACKAGE AND MANUFACTURING METHOD THEREOF

(71) Applicant: Orient Semiconductor Electronics, Limited, Kaohsiung City (TW)

(72) Inventors: Yueh-Ming Tung, Kaohsiung City (TW); Chia-Ming Yang, Kaohsiung City (TW); Tsun-Lung Hsieh, Kaohsiung City (TW); Guan-Lin Pan, Kaohsiung City (TW); Po-Yen Yen, Kaohsiung City (TW)

(21) Appl. No.: 18/606,094

(22) Filed: Mar. 15, 2024

(30) Foreign Application Priority Data
Aug. 14, 2023 (TW) 112130493

(51) Int. Cl. H01L 25/065; H01L 21/56; H01L 21/60; H01L 23/00; H01L 23/31; H01L 23/498

(52) U.S. Cl. CPC H01L 25/0655; H01L 21/568; H01L 21/60; H01L 23/3157; H01L 23/49816; H01L 24/11; H01L 24/13; H01L 2224/11; H01L 2224/13144; H01L 2224/13147

(57) ABSTRACT

The present disclosure provides a semiconductor package. The semiconductor package includes a first die, a plurality of first bonding pads, a plurality of first conductive bumps, a molding layer and a redistribution layer. The first die has a top surface and a bottom surface opposing to the top surface. The first bonding pads are disposed on the top surface of the first die. The first conductive bumps are disposed on the first bonding pads, and the first conductive bumps are electrically connected with the first die. The molding layer covers the top surface of the first die and exposes the first conductive bumps. The redistribution layer is disposed on the molding layer to electrically connect to the first conductive bumps. The present disclosure further provides a method of manufacturing the above semiconductor package.

### CROSS-REFERENCE TO RELATED APPLICATIONS

The present application is based on and claims priority to Taiwanese Application Number 112130493, filed Aug. 14, 2023, the disclosure of which is hereby incorporated by reference herein in its entirety.

### FIELD OF THE DISCLOSURE

This disclosure relates to a semiconductor package and a manufacturing method thereof, and more particularly relates to a semiconductor package having a redistribution layer, and a manufacturing method thereof.

### BACKGROUND OF THE DISCLOSURE

Existing semiconductor package structures made by flip die technology are usually not thin enough to meet the thinning requirements, and their manufacturing costs are high for power components with a small number of contacts.

### SUMMARY

In view of the above, the present disclosure provides a semiconductor package and a manufacturing method thereof, wherein a wire bonding process is used instead of a ball mounting process in order to reduce cost, and a redistribution process is utilized to reduce the overall thickness of the semiconductor package.

In one embodiment, the semiconductor package of the present disclosure includes a first die, a plurality of first bonding pads, a plurality of first conductive bumps, a molding layer and a redistribution layer. The first die has a top surface and a bottom surface opposing to the top surface. The first bonding pads are disposed on the top surface of the first die. The first conductive bumps are disposed on the first bonding pads, and the first conductive bumps are electrically connected with the first die. The molding layer covers the top surface of the first die and exposes the first conductive bumps. The redistribution layer is disposed on the molding layer to electrically connect to the first conductive bumps. The present disclosure further provides a method of manufacturing the above semiconductor package.

In one embodiment, the method of manufacturing a semiconductor package comprises: disposing a first die on a carrier, wherein the first die has a top surface and a bottom surface opposing to the top surface; forming a plurality of first conductive bumps on the top surface of the first die through a wire bonding process, wherein the first conductive bumps are electrically connected to the first die; forming a molding layer to cover the first conductive bumps and the first die; grinding the molding layer to expose the first conductive bumps; forming a redistribution layer on the molding layer to electrically connect to the first conductive bumps; and removing the carrier.

In the semiconductor package of the present disclosure, a wire bonding process is used instead of a ball mounting process in order to reduce cost, and a redistribution process is utilized to reduce the overall thickness of the semiconductor package to less than 0.15 mm.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package of the present disclosure.

FIGS. 2 to 10 illustrate the method of manufacturing the semiconductor package of FIG. 1.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

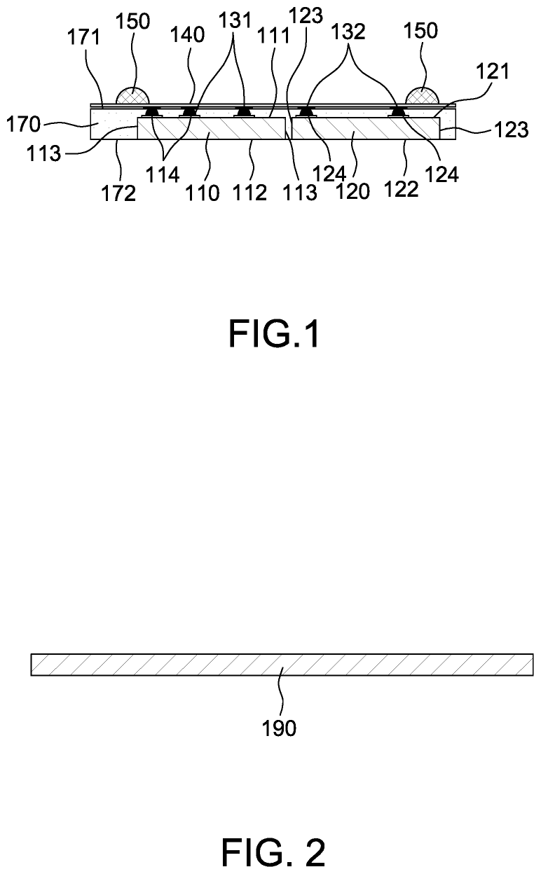

Referring to FIG. 1, the semiconductor package of the present disclosure includes one or more dies, such as a first die 110 and a second die 120, wherein the first die 110 and the second die 120 are arranged side by side.

The first die 110 has a first surface 111, a second surface 112, and a plurality of third surfaces 113, wherein the first surface 111 is an active surface. The first surface 111 and the second surface 112 are located on different planes. The third surfaces 113 connect the first surface 111 and the second surface 112. A plurality of first bonding pads 114 is formed on the first surface 111. In one embodiment, the first surface 111 is a top surface, the second surface 112 is a bottom surface, and the third surfaces 113 are side surfaces, but is not limited thereto.

The second die 120 has a first surface 121, a second surface 122, and a plurality of third surfaces 123, wherein the first surface 121 is an active surface. The first surface 121 and the second surface 122 are located on different planes. The third surfaces 123 connect the first surface 121 and the second surface 122. A plurality of second bonding pads 124 is formed on the first surface 121. In one embodiment, the first surface 121 is a top surface, the second surface 122 is a bottom surface, and the third surfaces 123 are side surfaces, but is not limited thereto.

A plurality of first conductive bumps 131 is respectively provided on the first bonding pads 114 of the first surface 111 of the first die 110, and is electrically connected to the first die 110 through the first bonding pads 114. A plurality of second conductive bumps 132 is respectively provided on the second bonding pads 124 of the first surface 121 of the second die 120, and is electrically connected to the second die 120 through the second bonding pads 124. The first conductive bumps 131 and the second conductive bumps 132 are made of conductive materials, such as gold, copper or alloys. In the present disclosure, the first conductive bumps 131 and the second conductive bumps 132 may be respectively formed on the first bonding pads 114 of the first die 110 and the second bonding pads 124 of the second die 120 through a wire bonding process using gold wires, copper wires, alloy wires, or other conductive wires. In one embodiment, the first conductive bumps 131 and the second conductive bumps 132 may be spherical or ball-shaped.

The semiconductor package of the present disclosure further includes a molding layer 170, which is made of a molding material, such as epoxy resin, but is not limited thereto. The molding layer 170 has a first surface 171 and a second surface 172 opposing to the first surface 171. The first surface 171 and the second surface 172 are located on different planes. For example, the first surface 171 is a top surface and the second surface 172 is a bottom surface. The molding layer 170 is formed on the first surface 111 of the first die 110 and the first surface 121 of the second die 120, and covers the third surfaces 113 of the first die 110 and the third surfaces 123 of the second die 120. The molding layer 170 is not formed on the second surface 112 of the first die 110 and the second surface 122 of the second die 120, and does not completely cover the first conductive bumps 131 and the second conductive bumps 132. Each of the first conductive bumps 131 and the second conductive bumps 132 is partially exposed from the molding layer 170. Therefore, the first surface 171 of the molding layer 170 is located above the first surface 111 of the first die 110 and the first surface 121 of the second die 120, and the second surface 172 of the molding layer 170 is flush with the second surface 112 of the first die 110 and the second surface 122 of the second die 120.

A redistribution layer (RDL) 140 is formed on the first surface 171 of the molding layer 170. There are conductive traces formed in the redistribution layer 140. The redistribution layer 140 extends from above the first surface 111 of the first die 110 to above the first surface 121 of the second die 120, and is connected with the first conductive bumps 131 and the second conductive bumps 132. The first die 110 is electrically connected to the second die 120 through the redistribution layer 140.

A plurality of solder balls 150 is disposed on the redistribution layer 140. The solder balls 150 are electrically connected to the redistribution layer 140. The first die 110 and the second die 120 may be electrically connected to an external circuit through the redistribution layer 140 using the solder balls 150.

Referring to FIGS. 2 to 10, which illustrate a method of manufacturing the semiconductor package of FIG. 1. As shown in FIG. 2, a carrier 190 is provided. The carrier 190 may be made of silicon wafer, glass, metal or other materials that may withstand high temperature.

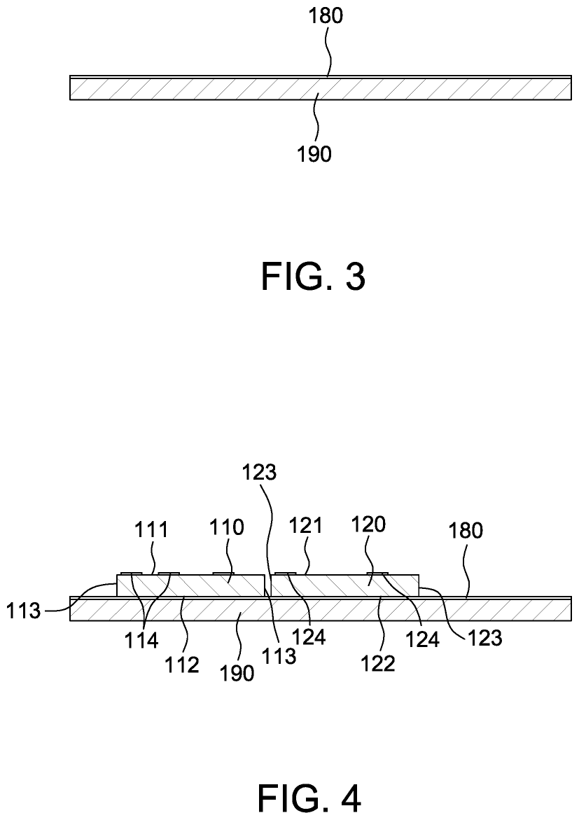

As shown in FIG. 3, a release material layer 180 is formed on the carrier 190 by coating or adhesion. The release material layer 180 is adhesive and releasable.

As shown in FIG. 4, one or more dies, such as a first die 110 and a second die 120 are adhered to the carrier 190 by the release material layer 180, wherein the first die 110 and the second die 120 are arranged side by side.

The first die 110 has a first surface 111, a second surface 112, and a plurality of third surfaces 113, wherein the first surface 111 is an active surface and the second surface 112 is adhered to the carrier 190. The first surface 111 and the second surface 112 are located on different planes. The third surfaces 113 connect the first surface 111 and the second surface 112. The first surface 111 is formed with a plurality of first bonding pads 114 thereon. In one embodiment, the first surface 111 is a top surface, the second surface 112 is a bottom surface, and the third surfaces 113 are side surfaces, but is not limited thereto.

The second die 120 has a first surface 121, a second surface 122, and a plurality of third surfaces 123, wherein the first surface 121 is an active surface and the second surface 122 is adhered to the carrier 190. The first surface 121 and the second surface 122 are located on different planes. The third surfaces 123 connect the first surface 121 and the second surface 122. The first surface 121 is formed with a plurality of second bonding pads 124. In one embodiment, the first surface 121 is a top surface, the second surface 122 is a bottom surface, and the third surfaces 123 are side surfaces, but is not limited thereto.

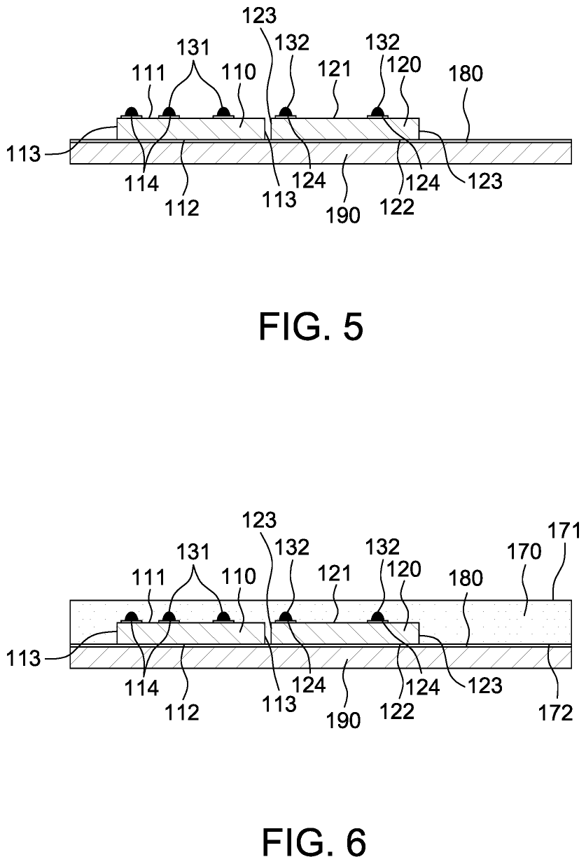

As shown in FIG. 5, a plurality of first conductive bumps 131 is then disposed on the first bonding pads 114 on the first surface 111 of the first die 110. A plurality of second conductive bumps 132 is disposed on the second bonding pads 124 on the first surface 121 of the second die 120. The first conductive bumps 131 are electrically connected to the first die 110 through the first bonding pads 114 and the second conductive bumps 132 are electrically connected to the second die 120 through the second bonding pads 124.

The first conductive bumps 131 and the second conductive bumps 132 are made of conductive materials, such as gold, copper or alloys. In the present disclosure, the first conductive bumps 131 and the second conductive bumps 132 may be respectively formed on the first bonding pads 114 of the first die 110 and the second bonding pads 124 of the second die 120 through a wire bonding process using gold wires, copper wires, alloy wires, or other conductive wires.

As shown in FIG. 6, a molding layer 170 covering the first conductive bumps 131 and the second conductive bumps 132 is then formed on the carrier 190 using an adhesive material, such as epoxy resin. The molding layer 170 has a first surface 171 and a second surface 172 opposing to the first surface 171. The first surface 171 and the second surface 172 are located on different planes. For example, the first surface 171 is a top surface and the second surface 172 is a bottom surface. The molding layer 170 is further formed on the first surface 111 of the first die 110 and the first surface 121 of the second die 120, and covers the third surfaces 113 of the first die 110 and the third surfaces 123 of the second die 120. The molding layer 170 is not formed on the second surface 112 of the first die 110 and the second surface 122 of the second die 120 since it is obscured by the carrier 190. The second surface 172 of the molding layer 170 is flush with the second surface 112 of the first die 110 and the second surface 122 of the second die 120.

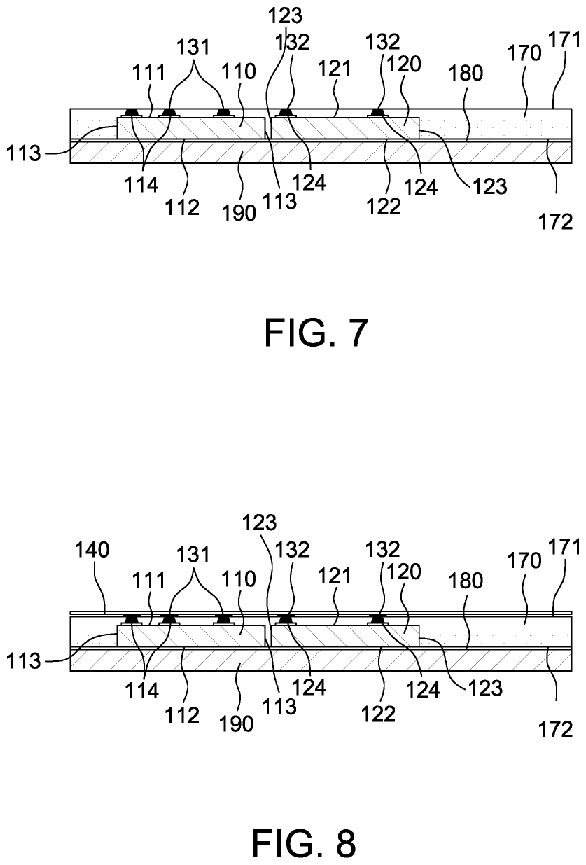

As shown in FIG. 7, the first surface 171 of the molding layer 170 is then ground to reduce the thickness of the molding layer 170 so that tops of the first conductive bumps 131 and the second conductive bumps 132 are exposed.

As shown in FIG. 8, a redistribution layer 140 with conductive traces therein is subsequently formed on the first surface 171 of the molding layer 170 by a redistribution process. The redistribution layer 140 extends from above the first surface 111 of the first die 110 to above the first surface 121 of the second die 120, and is connected with the first conductive bumps 131 and the second conductive bumps 132. The first die 110 is electrically connected to the second die 120 through the redistribution layer 140.

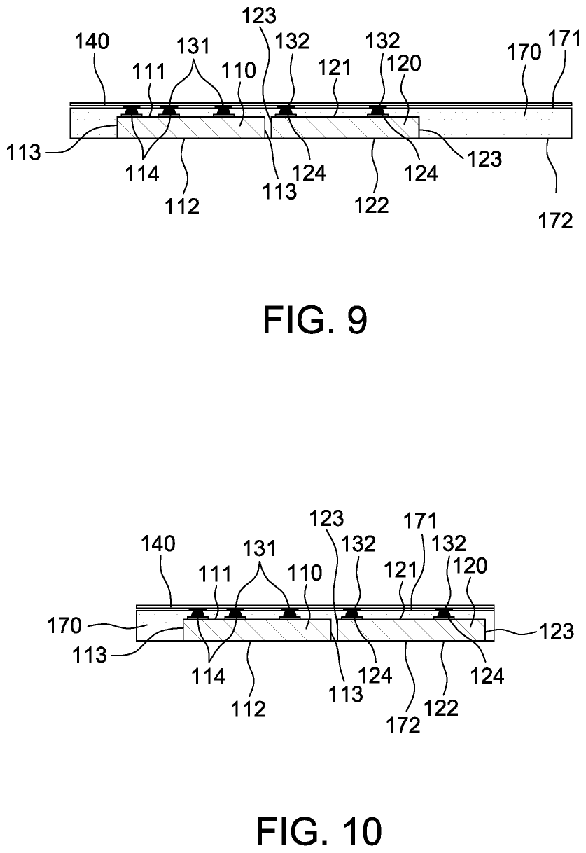

As shown in FIG. 9, the first conductive bumps 131 and the second conductive bumps 132 are then wire-redistributed to generate contacts used for electrical connection to an external circuit. Afterwards, the carrier 190 is removed.

As shown in FIG. 10, the molding layer 170 is then divided, and a plurality of solder balls 150 are formed on and electrically to the redistribution layer 140 so as to form a plurality of semiconductor packages of FIG. 1.

In the semiconductor package of the present disclosure, a wire bonding process is used instead of a ball mounting process in order to reduce cost, and a redistribution process is utilized to reduce the overall thickness of the semiconductor package to less than 0.15 mm.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A method of manufacturing a semiconductor package, comprising:
disposing a first die on a carrier, wherein the first die has a top surface and a bottom surface opposing to the top surface;
forming a plurality of first conductive bumps on the top surface of the first die through a wire bonding process, wherein the first conductive bumps are electrically connected to the first die;
forming a molding layer to cover the first conductive bumps and the first die;
grinding the molding layer to expose the first conductive bumps;
forming a redistribution layer on the molding layer to electrically connect to the first conductive bumps; and
removing the carrier.

2. The method as claimed in claim 1, further comprising:
disposing a second die on the carrier;
forming a plurality of second conductive bumps on the second die through a wire bonding process, wherein the second conductive bumps are electrically connected to the second die;
covering the second conductive bumps and the second die with the molding layer;
exposing the second conductive bumps from the molding layer; and
electrically connecting the redistribution layer to the second conductive bumps.

3. The method as claimed in claim 1, wherein the first conductive bumps are formed with one of gold wires, copper wires and alloy wires.

4. The method as claimed in claim 1, wherein the molding layer has a bottom surface that is flush with the bottom surface of the first die.

5. The method as claimed in claim 1, further comprising:
after forming the redistribution layer, disposing a plurality of solder balls on the redistribution layer, wherein the solder balls are electrically connected to the redistribution layer.

6. The method as claimed in claim 2, wherein the first die and the second die are disposed side by side on the carrier.

7. A semiconductor package, comprising:
a first die having a top surface and a bottom surface opposing to the top surface;
a plurality of first bonding pads disposed on the top surface of the first die;
a plurality of first conductive bumps disposed on the first bonding pads respectively, wherein the first conductive bumps are electrically connected to the first die;
a molding layer covering the top surface of the first die and exposing the first conductive bumps; and
a redistribution layer disposed on the molding layer to electrically connect to the first conductive bumps.

8. The semiconductor package as claimed in claim 7, further comprising:
a second die having opposing top and bottom surfaces;
a plurality of second bonding pads disposed on the top surface of the second die; and
a plurality of second conductive bumps disposed on the second bonding pads respectively, wherein the second conductive bumps are electrically connected to the second die; wherein
the molding layer further covers the top surface of the second die and exposes the second conductive bumps; and
the redistribution layer is further electrically connected to the second conductive bumps.

9. The semiconductor package as claimed in claim 7, wherein the molding layer has a bottom surface that is flush with the bottom surface of the first die.

10. The semiconductor package as claimed in claim 7, further comprising:
a plurality of solder balls disposed on the redistribution layer, the solder balls being electrically connected to the redistribution layer.
